(19) United States
(12) Patent Application Publication
(10) Pub. No.: US 2025/0273734 A1
(43) Pub. Date: Aug. 28, 2025

(54) APPARATUS, SYSTEM AND METHOD FOR BATTERY FORMATION

(71) Applicant: Iontra Inc, Centennial, CO (US)

(72) Inventor: Daniel A. KONOPKA, Aurora, CO (US)

(21) Appl. No.: 19/060,445

(22) Filed: Feb. 21, 2025

Related U.S. Application Data
(60) Provisional application No. 63/557,261, filed on Feb. 23, 2024.

(51) Int. Cl. H01M 10/0562; H01M 4/02; H01M 10/0525; H01M 10/44; H01M 10/48

(52) U.S. Cl. CPC H01M 10/0562; H01M 10/0525; H01M 10/44; H01M 10/484; H01M 2004/021

(57) ABSTRACT

A method of processing a battery including an electrode including pores filled with a gas involves applying a formation current to the battery, the formation current comprising at least one frequency attribute, the at least one frequency attribute based on an assessed dielectric attribute associated with wetting the pores with electrolyte. A method of processing a battery including a battery comprising an electrode involves applying a formation current to the battery comprising at least one frequency attribute, the at least one frequency attribute based on an assessed dielectric attribute associated with forming a solid electrolyte interphase (SEI) layer on the electrode.

### CROSS-REFERENCE TO RELATED APPLICATION

This application claims priority to U.S. Provisional Patent Application No. 63/557,261, filed Feb. 23, 2024, entitled “FORMATION,” the entire disclosure of which is hereby incorporated by reference, for all purposes, as if fully set forth herein.

### TECHNICAL FIELD

Aspects of the present invention involve processing a battery and particularly involve battery formation including electrode pore wetting and SEI layer formation.

### BACKGROUND AND INTRODUCTION

Before a battery can be used, it goes through a process typically referred to as “formation.” Generally speaking, a battery cell, and particularly any of a number of different forms of Lithium-Ion type battery cells, includes electrodes (anode and cathode) and electrolyte. The last step, or nearly last step, of the battery manufacturing process involves the formation step (or steps) where the assembled cell is cycled (charged and discharged) under precise conditions to form an SEI (solid electrolyte interphase) layer at the electrodes, primarily the anode. The charge and discharge portions of a cycle typically occur at a C/20 rate using a DC current (e.g., 20 hours to charge and 20 hours to discharge), and SEI formation typically requires more than one cycle (e.g., 4 to 6), which may thus take several days at such low charging and discharging rates. Formation also involves “wetting” where liquid electrolyte is forced to impregnate tiny pores between particles in the electrodes and replace any gas in those pores.

These formation steps, including SEI formation and wetting, are very important to the final performance of the cell. At a high level, proper formation leads to a battery being able to utilize its full possible capacity, among other performance related issues.

It is with these observations in mind, among others, that aspects of the present disclosure were conceived.

### SUMMARY

Aspects of the present disclosure involve a method of processing a battery comprising an electrode including pores filled with a gas, the method including applying a formation current to the battery, the formation current comprising at least one frequency attribute, the at least one frequency attribute based on an assessed dielectric attribute associated with wetting the pores with electrolyte. The assessed dielectric attribute represents a changing dielectric property of the electrode responsive to electrolyte replacing the gas in the pores of the electrode. The method further may include tuning the at least one frequency attribute based on the changing dielectric property. The at least one frequency attribute targets electrodynamic diffusion processes associated with optimizing wetting of relatively smaller pores with relatively higher surface tension that inhibits electrolyte from entering the pores. In a range of examples, the at least one frequency attribute is a harmonic in the range of 1 Ghz to 20 Ghz. In other examples, the at least one frequency attribute is 100 KHz or greater, 10 MHz or greater, or in the range of 3-15 GHZ. The frequency may depend on the anode type—e.g., graphite anode or transition metal-based cathode—the size of the anode or electrode more generally, or other attributes.

The method may further comprise obtaining at least one responsive attribute of a signal applied to the battery where the at least one responsive attribute is indicative of the assessed dielectric attribute. In some examples, the at least one responsive attribute is a peak value at a frequency mapped to the assessed dielectric attribute. In some examples, the assessed dielectric property is obtained from comparing at least one signal peak of a measured signal to a fingerprint that associates the at least one signal peak to a dielectric property. The measured signal may include reflected energy, return loss, transmission energy, or transmission loss.

Another aspect of the present disclosure involves a method of processing a battery comprising an electrode, the method including applying a formation current to the battery comprising at least one frequency attribute, the at least one frequency attribute based on an assessed dielectric attribute associated with forming a solid electrolyte interphase (SEI) layer on the electrode. The method may further comprise assessing SEI formation progress by comparing a fingerprint including at least one frequency value associated with a dielectric value of a target SEI layer with a signal including at least one frequency value associated with the dielectric value of the target SEI layer. The signal may include reflected energy, return loss, transmission energy, or transmission loss.

The method may further comprise altering the at least one frequency attribute of the formation current based on the comparison. The battery, in one example, is a lithium-ion battery and the electrode is an anode, and the SEI layer is on the anode and adjacent an electrolyte. In some instances, the SEI layer is completed without heating the battery.

Another aspect of the present disclosure may involve a method of forming a battery comprising applying a formation signal to the battery to form a solid electrolyte interphase layer or wetting pores of an electrode with electrolyte, the formation signal comprising a leading edge shaped according to a sinusoid followed by a constant current portion, and an alternating current sinusoidal electrokinetic formation portion. In some instance, the alternating current sinusoidal electrokinetic formation portion is in the range of 1 Ghz to 10 Ghz, although other ranges and starting values are possible as discussed herein. The alternating current electrokinetic sinusoidal portion may be applied during a rest period following the constant current portion, may be applied during the rest period following the constant current portion as a half wave rectified alternating current or full wave rectified alternating current, and/or may be applied on the constant current portion.

Another aspect of the present disclosure involve a formation apparatus/system comprising a fixture configured to hold a battery undergoing formation, the battery comprising at least one electrode and defining a periphery of the at least one electrode, the fixture defining a conductive chargeable surface adjacent the periphery of the at least one electrode, and the system configured to charge the peripheral conductive surface while the battery is undergoing formation. The peripheral conductive surface may be positively charged, negatively charged, or charged with an alternating charge.

These and other aspects of the present disclosure are described further below.

### BRIEF DESCRIPTION OF THE DRAWINGS

The foregoing and other objects, features, and advantages of the present disclosure set forth herein will be apparent from the following description of particular embodiments of those inventive concepts, as illustrated in the accompanying drawings. It should be noted that the drawings are not necessarily to scale; however, the emphasis instead is being placed on illustrating the principles of the inventive concepts. Also, in the drawings the like reference characters may refer to the same parts or similar throughout the different views. It is intended that the embodiments and figures disclosed herein are to be considered illustrative rather than limiting.

FIG. 1 is a process diagram illustrating a method of processing a battery and more specifically of generating a battery formation signal, in one example.

FIG. 2 is a system diagram of a formation system used to probe a battery to obtain an energy balance response, assess that response such as through comparison to a response fingerprint reflective of a state of wetting, SEI formation or otherwise, and apply a formation signal responsive to the same.

FIG. 3 shows two examples of different electrode (e.g., anodes) with relative porosity based on film thickness.

FIG. 4A illustrates a first example of a formation signal with a charging portion having a leading edge and or a formation portion falling between charging portion, with the leading edge and/or formation portions defined based on the technique of FIG. 1 or otherwise optimized at a frequency shape or frequency optimized for formation.

FIG. 4B illustrates a second example of a formation signal with a charging portion having a leading edge and or a formation portion falling between charging portion, with the leading edge and/or formation portions defined based on the technique of FIG. 1 or otherwise optimized at a frequency shape or frequency optimized for formation.

FIG. 4C illustrates a third example of a formation signal with a charging portion having a leading edge and or a formation portion integrated on a body portion of the charging portion, with the leading edge and/or formation portions defined based on the technique of FIG. 1 or otherwise optimized at a frequency shape or frequency optimized for formation.

FIG. 4D illustrates a fourth example of a formation signal with a charging portion having a leading edge defined based on the technique of FIG. 1 or otherwise optimized at a frequency shape or frequency optimized for formation. Note, the frequency of the charging portions, the time length of the charging portion versus the time length of the rest portion (or formation portion when considering FIGS. 4A and 4B), may be tailored for formation.

FIG. 5 illustrates a fixture for generating and applying an electric field to a battery cell undergoing to formation.

FIG. 6 is a diagram illustrating an example of a computing system which may be used in implementing embodiments of the present disclosure.

### DETAILED DESCRIPTION

Aspects of the present disclosure involve improvements in battery cell formation, and particularly methods where battery formation may be performed relatively more efficiently and/or effectively than conventional techniques. Aspects of the present disclosure involve unique formation signals that are more effective than conventional DC charge or discharge signals. Aspects of the present disclosure further involve unique ways of assessing aspects of formation such as pore degassing and electrolyte replacement and SEI formation, and acting on those assessments to alter the formation signal in some way. Aspects of the present disclosure further involve a unique apparatus that is beneficial for formation. The inventive methods and systems discussed herein may be used in a variety of battery cell types. Thus, while the techniques and system discussed herein may be illustrated with reference to a Lithium-Ion battery cell including a liquid electrolyte and a graphite anode, the inventive techniques and systems are not so limited.

Prior to a battery cell being complete and able to be used, the porous structure of a graphite anode is initially filled with gas which must be displaced with electrolyte in a process referred to as wetting for Li ions to eventually access the full surface area of the graphite anode. In some instances, some gas may have been expelled under vacuum processing. Nonetheless, wetting is complex because the graphite contains a range of pore sizes which degas at different rates and require different levels of energy to do so. Once present in the pores, the electrolyte reacts with lithium at the electrode surface to form oxidized lithium species in the micro-pores as well as on the flat surface at the electrode/electrolyte interface, the latter of which is what is typically referred to as SEI (solid electrolyte interphase) formation. In conventional techniques, both of these process steps-wetting and SEI formation—are relatively slow for a number of reasons including 1) relatively smaller pores are more difficult to penetrate with electrolyte, 2) fast rates/high charge and discharge currents cannot be used as it may block off some of the porosity from electrolyte penetration, decreasing electrochemically active surface area (as compared to a cell with a higher proportion of the pores being wetted), which results in a relative decrease in rate capability of the cell as compared to the same cell had it been more fully wetted (less gas remaining in pores).

Aspects of the present disclosure involve a formation signal including one or more components that when applied to a battery undergoing formation cause no or the least amount of phase shift at the anode when applied to the battery undergoing formation. The formation signal may include at least one harmonic feature, which signal may be applied at relatively higher currents than would be possible and would be destructive if done with conventional DC power. For example, a leading edge of a formation charge or a leading edge of a formation discharge signal may be shaped to correspond to a partial sine wave (e.g., approximately 90 degrees of a sine wave starting with 0 amp current to a maximum magnitude current) where the sine wave shape corresponds to a frequency of the sine wave based on a harmonic with a relatively low or the lowest impedance when applied to the battery. A low impedance signal is understood to affect a relatively lower amount of phase shift at the anode as compared to a higher impedance signal. In addition to or alternative to the shaped leading edge, the formation signal may involve an alternating current signal. In one example, in the various formation signals discussed herein it is possible to conduct formation at a relatively higher magnitude current without the damaging effects of non-uniformities that would otherwise build up in a conventional process and while still providing a uniform SEI layer. The select application of a specific formation signal wave shaped based on a harmonic (or harmonics) in the formation signal may target different pore sizes, inducing controlled electric fields inside some pores which accelerate their conversion (e.g., degassing and electrolyte penetration), while leaving other pores safe and healthy. The examples discussed herein illustrate various aspects of a formation signal based on a single harmonic at some frequency. Various aspects of a formation signal may be comprised of additional harmonic components.

The systems and methods discussed herein may also provide a relatively more accurate end point to the formation process by detecting the completion of the wetting and/or SEI formation portions of formation. This may also have the additional benefit of producing a relatively higher proportion of high-quality so-called A grade cells as opposed to other lower B and C grade cells. These and other advantages of the aspects of the present disclosure are discussed in detail herein.

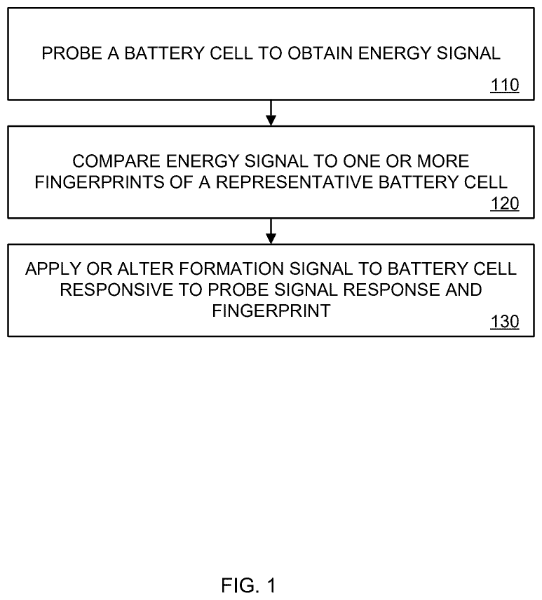

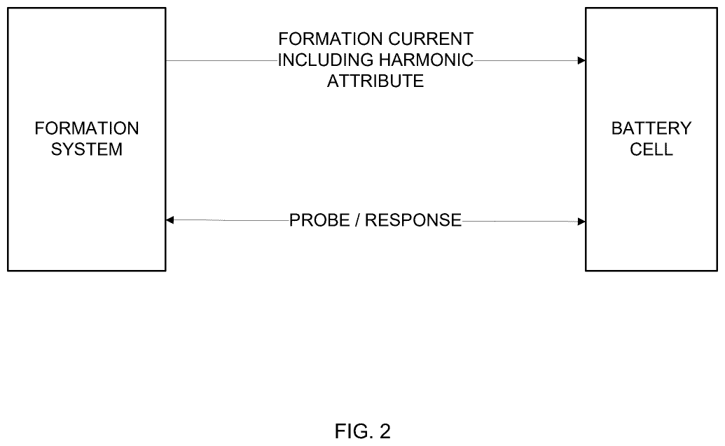

FIG. 1 is a flowchart illustrating a method 100 of forming a battery cell in accordance with aspects of the present disclosure. FIG. 2 is a system diagram illustrating one example of a system that may be used to practice the forming method shown in FIG. 1. To begin, the system may apply a probing signal to the battery cell (operation 110). The signal may be applied at one or both tabs, referring to an example of a pouch cell configuration. In other alternatives, the signal may be applied at a lead or leads operably coupled with the anode and/or cathode of the battery, may be applied by way of probes directly to the anode—e.g., two different points on the anode or the associated current collector, may be connected to current collectors associated with the anode or cathode, or at other possible locations.

In some examples, the signal may comprise a frequency or range of frequencies intend to obtain a battery cell response that is frequency dependent. During this process traditional analysis like EIS (electrochemical impedance spectroscopy) will be highly convoluted, and the porosity state cannot be distinguished from high initial impedance of the electrode from other causes. In contrast and for example, the probing signal may be used to measure or otherwise obtain one or more attributes including impedance, return loss, transmission loss, reflected energy, and transmitted energy. In general, the system is measuring or otherwise obtaining an attribute or attributes related to the energy/an energy balance of the battery undergoing formation. The probing signal applies energy to the battery, and, for example, some of the energy is reflected back (return loss), some passes through the battery (transmission loss), some is radiated, and some is lost as heat (resistive losses). All of these losses will add up to about the original input energy subject to error and other losses unrelated to the battery. The system can collectively account for any or each of these energy measurements in the “energy balance” of the system. In various examples, the probing signal will involve a sweep across a range of frequencies, which may involve several probing signals each at various frequencies, with the various possible attributes obtained at the various frequencies. Aspects of the disclosure involve the discovery and recognition that peaks in the measurements will occur at different frequencies. So, there will be a peak reflected energy, if that is the attribute being measured, at a certain frequency or set of peak reflected energies at a range of frequencies. For example, there may be a range of reflected energies that meet some threshold and thus may collectively be considered to fall within what is considered a peak.

Moreover, aspects of the disclosure involve the recognition that the peak location, range, and/or width may correlate to dielectric properties of the material. It is generally understood that the dielectric constant, also referred to as relative permittivity, of a material refers to its ability to store electric energy in an electric field. Moreover, the dielectric property may correspond to combined effects of the electrode material, e.g., graphite, the pore size and spacing, the material (or lack thereof) in the pores, and other attributes. Aspects of the present disclosure involve assessing the dielectric properties of a material, e.g., an anode, as it is being formed, and assessing degassing and/or SEI formation based on the same. In various aspects, the dielectric constant of air, which may be on the order of 1, is significantly different from the dielectric property of electrolyte, which may be on the order of 30-50 depending on the electrolyte. The graphite itself may have a dielectric constant (or relative permittivity) of 10-15. Hence, as air in pores is replaced with electrolyte, for example, the dielectric property of the material will change as relatively more of the total volume is reflective of the presence of electrolyte in the pores as opposed to air in the pores. So, when the pores are filled with air or evacuated, the dielectric constant will be less than the constant of graphite itself, and then will change to being greater than graphite alone as the pores are filled with the higher dielectric constant electrolyte.

Similarly, as the SEI layer and other SEI formation occurs, the dielectric property of the material will change. The permittivity of the anode pores will become less insulating at formation progresses. On the other hand, the permittivity of the SEI on top of the anode will become more insulating. In some possible situations, it is believed that changes in the pores and changes in the SEI will be indicated at separate and distinguishable frequencies because the area of the pores is so much greater than that of the SEI, and also because the starting permittivity should be sufficiently different from one another.

The dielectric constant (ε′, real number, how easily a material polarizes and stores energy) is relatively flat, and the tendency of the material to dissipate energy (ε″, imaginary number, energy lost from leakage current) may not be. Whatever the trend, the relationship between ε′ & ε″ is analogous to the real and imaginary parts of impedance calculation. Hence, in some examples, the system may probe the battery during formation to obtain impedance, which may include the real and imaginary parts thereof, and act on impedance to define the formation signal.

In various possible implementations, because of the types of attributes the system is assessing, a relatively high frequency—e.g., 1-20 Gigahertz (or more) probing signal and range of signals may be used. The signal speed is important in that it allows the system to take advantage of higher frequencies and significant variations in dielectric properties of graphite as compared to gas (or air), as compared to electrolyte, and/or as compared to SEI to precisely monitor the progress of formation without the probing signals themselves impacting the electrochemical processes. That is, the system can use probing signals which are sufficiently fast (high frequency) as to avoid any damaging electrochemical response. As will be recognized from the discussion below, it is also possible to include a relatively high frequency signal, in addition to the formation signal, to further effect wetting and SEI formation, where the signal is at sufficiently high frequency that it has an electrokinetic effect but little or no electrochemical response.

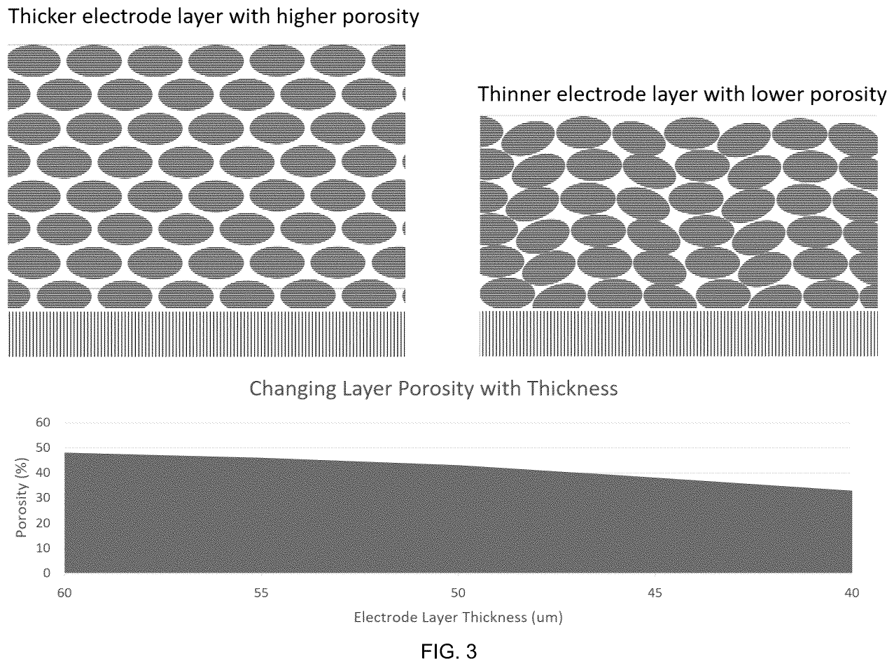

FIG. 3 shows examples of different electrode examples with relative porosity based on film thickness. The film thickness may be upon deposition onto a carrier or current collector and may or may not reflect any form of densification processing that may be used to reduce pore size and enhance material contact of the particles forming the electrode.

Returning to the method of FIG. 1, the system may further access a fingerprint or fingerprints representative of some aspect of the battery cell (operation 120). For example, an ideal sample or samples of a battery cell may be characterized, and a fingerprint generated for the sample (or samples). For example, if the system is using a reflected energy measurement, the system may access reflected energy fingerprints for the battery cell type undergoing formation. A fingerprint may be correlated to pore wetting with a fingerprint related to the start of formation and a fingerprint correlated to the end of formation (when pores are fully wetted (degassed)). As noted above, as pores degas and air is replaced with electrolyte (and/or electrolyte fills pores that have been evacuated), the dielectric constant of the anode will change from one that is based in part on the pores containing air to one that is based in part on pores with electrolyte. The change in the dielectric property may be identified by a change in peaks, location and or width, of the reflected energy signal. Similarly, a fingerprint or fingerprints may be associated with SEI formation.

In one example, a fingerprint includes impedance, return loss, transmission loss, reflected energy or transmitted energy frequency responses of a characterized sample of a battery undergoing formation. As noted above, the fingerprints may be obtained at the start of a formation process, at points during processing, and of a sample when formation is complete. Further, in some instances, the system may have fingerprints at time intervals such that formation progress may be assessed by comparing signal responses at corresponding time intervals, as discussed further below.

The system and method may use the fingerprint to assess formation progress, assess the rate of formation, assess an end point, assess whether a change in the formation signal would be advantageous, assess the type of change in the formation signal, and various combinations of the same. As such, the system may define the formation signal based on a comparison between the probe signal response and one or more fingerprints (operation 130). For example, the system may include a fingerprint indicative of a completed formation step, whether that formation step be wetting, SEI formation, or otherwise. The system may thus compare the current probe signal result (return loss, etc.) with a fingerprint for the end of formation, and when the two match, which may be within a threshold value or range, the system may end the formation step. In another example, the system may include a series of fingerprints with a time component, that collectively indicate progress of a formation step. The system may thus assess formation progress by comparing the result of a probe signal at certain times with the associated fingerprint.

The formation signal may be altered based on the determined rate of formation to alter some aspect of the formation signal, which may affect an increase in the rate of formation (e.g., rate of degassing and/or rate of SEI formation). An increase in rate is not necessarily the goal; in some instance, for example, the rate may be decreased to ensure that small pores are sufficiently degassed as compared to larger pores. If formation is moving at a lesser rate than is possible when comparing to the series of fingerprints, some attribute of the formation signal may be altered to increase the formation rate. The attribute may be nominal current, a harmonic attribute, a signal width, a rest period length, or other attribute. In the case of a harmonic attribute, the leading edge of a signal may be tuned to the shape of a different harmonic frequency. For example, it may be understood that a shorter wavelength (higher frequency) signal may be more suitable to wetting relatively smaller pores. Hence, the leading edge 412 of the signal may be shaped according to the higher frequency. The shape may thus be based on the shape of the higher frequency sinusoid. As such, depending on hardware capability, the leading edge may be formed in various ways including a linear piecewise approximation of a sinusoid. In the specific case of a linear piecewise approximation of a sinusoidal shape, each leading edge may be formed of a linear piecewise approximation including at least three linear segments having different slopes. In another example, an alternating current (AC) sinusoidal formation current signal may be applied during a rest period of the signal (noting that the rest period may include a DC current signal of some magnitude lesser than the preceding portion of the signal with the AC sinusoid being offset from 0 due to the DC current), a body portion of the signal following a shaped leading edge, or a combination. In another example, a conventional DC formation charge or discharge signal may be applied to the battery in combination with an AC component or range of AC components, e.g., a sinusoid defining a pulse or series of pulses such as in a full or half wave rectified AC signal, or otherwise, overlaid or applied in combination with the DC formation charge or discharge signal. So, for example, a C/20 or similar relatively low-rate DC current may be applied in combination with a formation optimizing signal intended to deliver an electrokinetic and/or thermal effect that enhances degassing, for example, thus making the overall formation relatively more effective than a C/20 signal standing alone.

The system also facilitates the strategic use of calculated higher frequencies to increase the diffusion of reactants into the pores and to the electrode surface via electrodynamic effects without requiring electrochemical reactions (that is, cause diffusion without requiring decomposition).

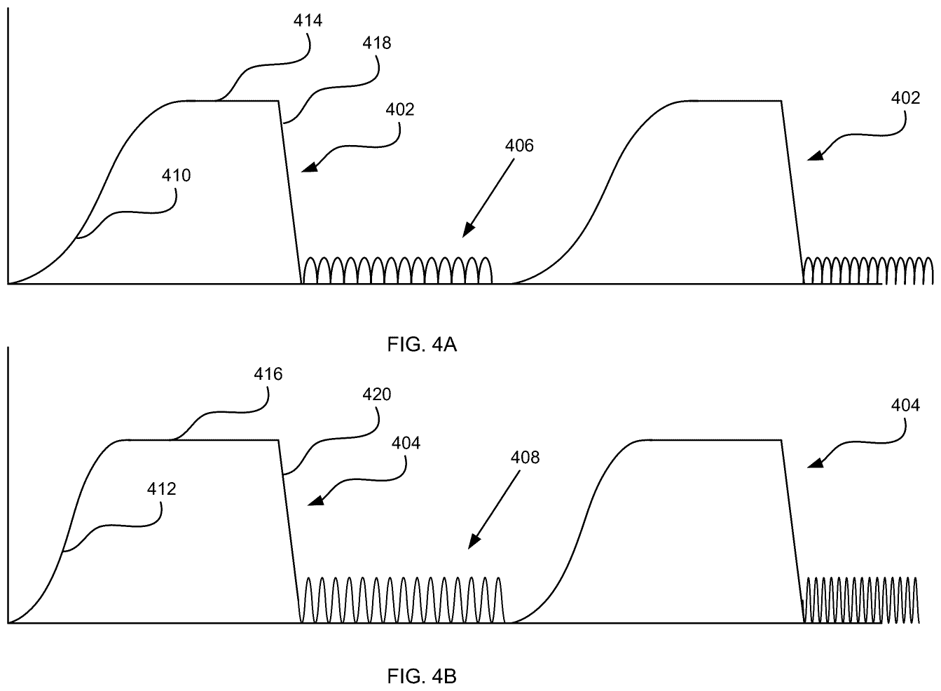

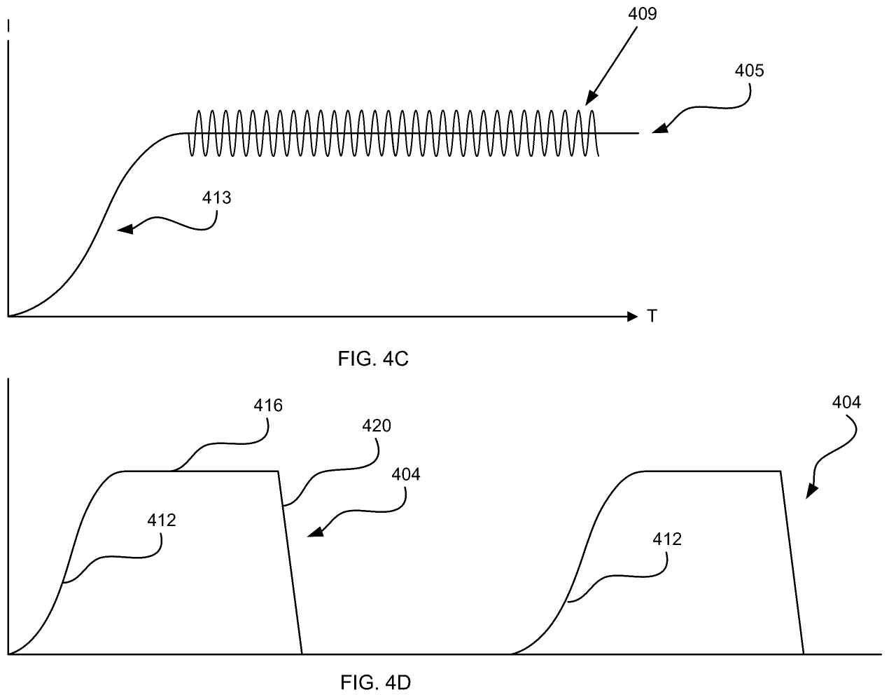

FIGS. 4A-4D are examples of different possible formation signals, each representing current to or from a battery undergoing formation. The various possible formation signals include formation signal features that may be used, alone or in combination, to form different possible example formation signals. Moreover, other examples are discussed herein. As such, the examples of FIGS. 4A-4D are meant to be illustrative and not limiting.

The formation signal may include a charge (or discharge) portion 402, 404, and 405 and a formation portion 406, 408 and 409; however, the entire signal may be considered a formation signal. The examples of FIGS. 4A and 4B show a repeating pattern of charge (or discharge) portions followed by formation portions. It should be recognized that the shaped leading edge of the charge (discharge portion) is also considered a formation portion. In contrast, the example of FIG. 4C shows a formation portion overlaid on a relatively constant DC current portion of the the charge portion, following the shaped leading edge. In general, a formation signal may include a sequence of some number of charge portions, and formation portions. Alternatively or additionally, the formation portion may be overlaid with the charge (discharge) portion as shown in FIG. 4C, which may also be overlaid on a conventional formation signal such as a C/20 constant current charge or discharge formation signal. The length (time) of the charge portions and the formation portions may vary. The term charge portion is used herein to reflect the positive current being applied to the cell undergoing formation, with the term discharge portion used to reflect a positive current from the cell undergoing formation, noting that in both cases the battery is not fully formed and hence may not be considered to be undergoing charge or discharge while still being formed.

In the example illustrated in FIG. 4D, the leading edge 412 of the charge portion 404 may be tailored to provide formation efficiencies (similar leading edges are illustrated in FIGS. 4A, 4B and 4C). In this example, there is a rest period 422 (no charge or discharge current) or some DC offset, and the leading edge 412 of the charging portion is tuned (shaped) to provide the formation efficiencies. As noted above, for example, the shape of the leading edge may correspond to a portion of a sine wave at a frequency based on an assessment of impedance. The frequency may be selected based on a harmonic that has a relatively low impedance compared to other assessed harmonics, or may be predetermined based on battery characterization of such impedances, among others. The frequency may be selected to correspond to a signal that when applied to the battery produced the least amount of phase shift between current and voltage measurements at the anode. It should be recognized that hardware and/or measurement limitations may result in a leading edge that is within some range of an optimal frequency but not at the precise frequency for the lowest impedance or least amount of phase shift, or other attribute. Nonetheless, in some cases, the leading edge may also be tailored to provide formation efficiencies alone or in combination with the formation portion during a rest period or applied to a charge portion.

In still other examples, the leading-edge shape/body portions/rest portions of a formation signal may be dictated by rates of chemical processes occurring within the cell (e.g., at the anode). The formation portion of the signal, whether in the rest period, integrated in the leading edge or otherwise, may be used to accelerate chemical processes (increase kinetics and diffusivity) in the cell. While the formation portions are described in the context of a sinusoidal shape or sinusoidal alternating current signal (and approximations thereof), the formation signal may have different or other attributes, as well.

In the examples illustrated, the charge portions 402, 404 and 405 of the formation signals may include a sinusoidally shaped or otherwise more generally a shaped non-abrupt leading edge 410, 412 and 413 followed by a body portion 414, 416 (and 405), which terminate at a falling edge 418, 420 with regard to FIGS. 4A, 4B and 4C. The leading edge (e.g., leading edges 410 or 412) in many instances may not be an immediate very high frequency edge, such as in a square wave, to avoid injecting unintended high frequency harmonics when formation is initiated. As noted herein, the leading edge may be shaped based on the shape of a sinusoid associated with a frequency based on impedance measurements or more generally minimizing phase shift at the anode in the presence of the leading edge. The leading edge is followed by the body portion 414 which may be a constant current of some magnitude matching the maximum current magnitude when the leading edge terminates. The leading edge is shown as being followed smoothly by the body portion current; however, it is possible to have some other transition depending on how the leading edge is formed versus how the body portion is formed among other things.

Referring to FIG. 4A, the electrokinetic formation portion 406 falls between the charge (or discharge) portions (e.g., following a steady state charge or discharge portion 414) and is defined by a full (shown) or half wave rectified high frequency sinusoidal electrokinetic formation signal centered about zero amps, noting what would be negative going portions are rectified and cancelled or positive and hence there is not a negative going portion of the signal. A full wave rectifier may be used and hence a full wave rectified signal is shown in FIG. 4A, but it would also be possible to employ a half bridge. In this example, the formation portion is a rectified sinusoidal signal. As such, the sinusoid includes repeating positive (charge) current portions. The frequency of the formation portion, in some examples, should be sufficiently high to have an electrokinetic effect but not an electrochemical effect. The formation portion of the charging signal discussed in FIG. 4B, has some DC offset and is not rectified with the DC offset ensuring that the signal does not have a negative discharge portion (a portion reversing the current—e.g., if charging, there is not a negative going portion which could result in a momentary discharge). Hence, the magnitude of the sine wave is less than the magnitude of the DC offset in the formation portion of the signal shown in FIG. 4B. In various possible examples, the range of frequencies for the sinusoidal formation portion of the signal may be 1-10 GHz or higher.

In the example of FIG. 4C, a high frequency formation alternating current signal is overlaid on a DC portion 405 of a formation signal, which DC portion with overlaid AC signal may follow a shaped leading edge 413. In this example, the high frequency alternating current signal may be used in conjunction with the DC signal. Here, using a C/20 conventional formation signal for comparison, it may be possible to use a relatively larger rate DC current signal (e.g., higher rate than C/20), because of the presence of the formation signal overlaid on the DC current. Further, the formation signal may allow for more rapid wetting and controlled formation, whether or alone or through fingerprint comparisons.

The system may understand that a change in the frequency of these various attributes, e.g., shaped of leading edge, applied during rest, and/or applied on the body, of the formation signal may increase the rate of wetting relatively smaller pores. Similarly, the rate of formation (e.g., determined by comparison to fingerprints) may be illustrative of relatively larger pores having been fully wetted, which may be the target of the initial signal. In some instances, the system may initially target a certain pore size and change targeting over time. For example, the system may initially target relatively smaller pores with a relatively higher frequency formation feature and change targeting as the rate of wetting decreases indicating that the smaller pores are complete. The system may, alternatively, target larger pores and change to targeting relatively smaller pores over time. Hence, one or more fingerprints may be assessed and relate to pore wetting with the system adjusting the frequency of the formation portion of the signal relative to the fingerprint.

In other instances, the system may alter a frequency attribute and assess its effect on wetting rate. If the rate increases, the system may maintain the frequency attribute. The system may also iterate through alternative attributes until an optimal, e.g., the highest rate, is achieved, and then periodically reassess.

Generally speaking, besides targeting pores, the system may also use a relatively larger current than possible with conventional DC oriented formation processes (e.g., formation at C/20 rate). The system may selectively apply formation signals at higher relative currents which would be destructive with DC power, targeted to different pore sizes, inducing controlled electric fields inside some pores which accelerate their conversion, while leaving other pores safe and healthy. So, for example, referring again to FIG. 4C, if a conventional system used a C/20 rate, then the rate for the DC current portion 405 may be relatively higher due to the presence of the formation signal 409.

The system may assess progress with or without comparison to a fingerprint or fingerprints. For example, the system may assess or otherwise analyze saturation in feedback signals, indicating that changes (formation) in pore wetting or SEI formation are slowing and near completion, and act on the same. The system may also take as inputs the material and mechanical properties of the battery or battery components. From those, the system could calculate “fingerprints” rather than measuring them.

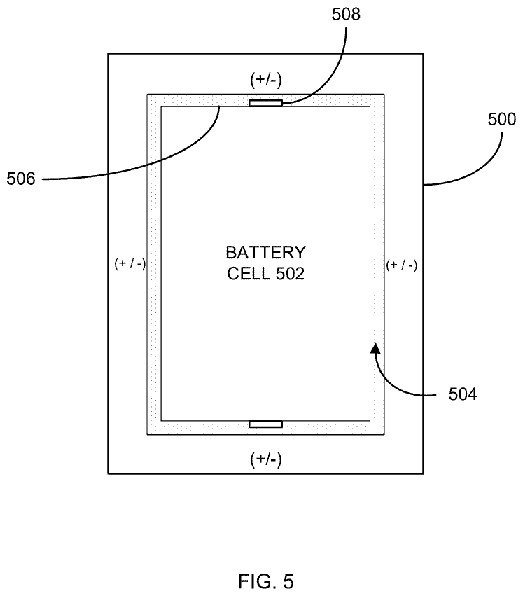

Another aspect of the present disclosure involves a fixture 500 or other arrangement whereby a battery cell 502 (or cells) undergoing formation may be subjected to an electric field 504 may be presented adjacent but not necessarily in contact with edges 506 of a discrete electrode, electrodes, or cell assembly (including one or more electrodes) undergoing formation. FIG. 5 is a plan view of the fixture 500 in which a cell including one or more stacked rectangular generally planar electrodes as might be found in a pouch cell. In FIG. 5, the battery cell may be a pouch cell, in which case the electrode inner edge may be inwardly offset from the outer edge of the pouch encasing the electrodes (and other cell components). In this example the fixture defines a rectangular boundary, which may be positively or negatively charged to generate the electric field 504, surrounding but not in contact with the outer edges of the electrodes of the cell undergoing formation. The field may be uniform or non-uniform, continuous or discontinuous, and combinations of the same. In one example, the fixture may include an electromagnetic arrangement which may control the initiation, strength, and/or direction of any electric field produced by the same. In another example, an electric charge may be imposed on the fixture, such as from the system providing the formation current.

In one example, the design of the cell may be limited by the occurrence of edge effects (higher current density along the edges of the battery electrodes). In such a situation, the fixture may be uniformly charged (+) to repel positive lithium ions away from the edges of the electrode. In another example, a large electrode, such as may be present in a relatively larger size pouch cell used in an automotive battery pack and the like, may be limited by an ohmic drop that occurs across the length of the electrode. In such a situation, the fixture may be non-uniformly charged: for example, the frame would be negatively charged near areas of the electrode which incur the largest ohmic drop so as to increase the attraction of positive lithium ions to that area. These examples are not limiting but instead presented to illustrate options in the configuration and use of a fixture, and the different field types that may be generated from the same to enhance formation, alone or in conjunction with the other techniques described herein.

By inducing an electric magnetic field at the outside edge boundaries of an electrode, here along the four edges of a rectangular electrode, formation current electrons and diffusing ions may be relatively more evenly distributed through the electrode. Depending on the arrangement, the field may be oriented to attract the electrons or conversely repel ions—e.g., by generating a mildly positive (+) field to attract electrons or repel ions. In such an arrangement, if electrons are introduced at a tab 508, which may be connected to a current collector in electrical communication with an electrode, along any particular edge, the electric field along all the edges helps draw electrons in the direction of all four edges and hence across the surface of the electrode The field may also alter the flow of ions across and through the electrode (or between electrodes and the electrolyte). The field may also be oriented to repel electrons or attract ions—e.g., by generating a mildly negative (−) field to repel electrons or attract ions. The magnetic field may also be alternated between positive and negative, which may in some cases help “shuffle” the electrons into various pores etc. The field strength, alteration, polarity and other attributes alone or in combination may be tailored through experimentation. It should be noted that the electrical response of electrons and ions to an electric field may be influenced and dependent on the unique chemical, material, and other properties of any given battery type.

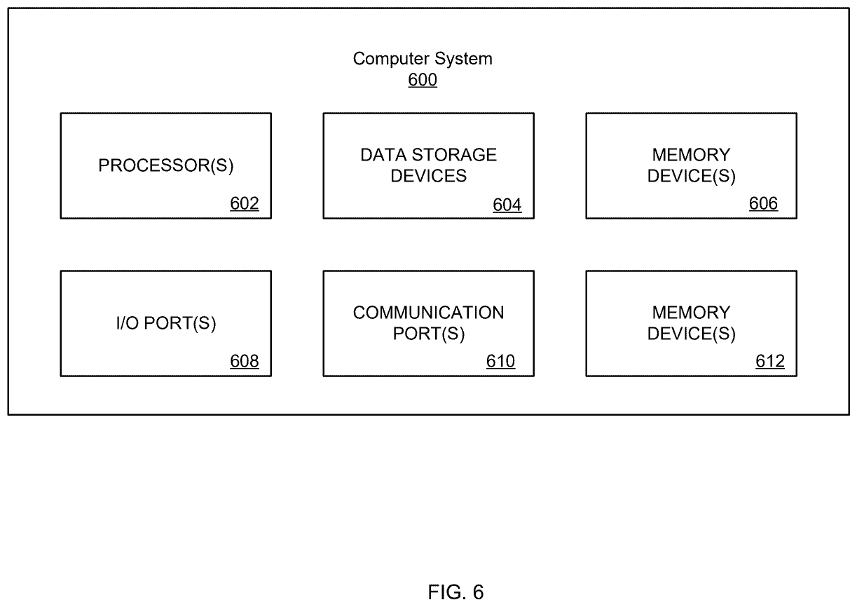

Referring to FIG. 6, a detailed description of an example computing system 600 having one or more computing units that may implement various systems and methods discussed herein is provided. The computing system 600 may be part of a controller, may be in operable communication with various implementation discussed herein, may run various operations related to the method discussed herein, may run offline to process various data for characterizing a battery, and may be part of overall systems discussed herein. The computing system 600 may process various signals discussed herein and/or may provide various signals discussed herein. For example, battery measurement information may be provided to such a computing system 600. The computing system 600 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 600 may be a computing system that is capable of executing a computer program product to execute a computer process. Data and program files may be input to the computer system 600, which reads the files and executes the programs therein. Some of the elements of the computer system 600 are shown in FIG. 6, including one or more hardware processors 602, one or more data storage devices 604, one or more memory devices 606, and/or one or more ports 608-612. Additionally, other elements that will be recognized by those skilled in the art may be included in the computing system 600 but are not explicitly depicted in FIG. 6 or discussed further herein. Various elements of the computer system 600 may communicate with one another by way of one or more communication buses, point-to-point communication paths, or other communication means not explicitly depicted in FIG. 6. Similarly, in various implementations, various elements disclosed in the system may or not be included in any given implementation.

The processor 602 may include, for example, a central processing unit (CPU), a microprocessor, a microcontroller, a digital signal processor (DSP), and/or one or more internal levels of cache. There may be one or more processors 602, such that the processor 602 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 604, stored on the memory device(s) 606, and/or communicated via one or more of the ports 608-612, thereby transforming the computer system 600 in FIG. 6 to a special purpose machine for implementing the operations described herein.

The one or more data storage devices 604 may include any non-volatile data storage device capable of storing data generated or employed within the computing system 600, such as computer executable instructions for performing a computer process, which may include instructions of both application programs and an operating system (OS) that manages the various components of the computing system 600. The data storage devices 604 may include, without limitation, magnetic disk drives, optical disk drives, solid state drives (SSDs), flash drives, and the like. The data storage devices 604 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), flash drives, and the like. Examples of non-removable data storage media include internal magnetic hard disks, SSDs, and the like. The one or more memory devices 606 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 604 and/or the memory devices 606, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 600 includes one or more ports, such as an input/output (I/O) port 608, a communication port 610, and a sub-systems port 612, for communicating with other computing, network, or vehicle devices. It will be appreciated that the ports 608-612 may be combined or separate and that more or fewer ports may be included in the computer system 600. The I/O port 608 may be connected to an I/O device, or other device, by which information is input to or output from the computing system 600. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 600 via the I/O port 608. In some examples, such inputs may be distinct from the various system and method discussed with regard to the preceding figures. Similarly, the output devices may convert electrical signals received from computing system 600 via the I/O port 608 into signals that may be sensed or used by the various methods and system discussed herein. The input device may be an alphanumeric input device, including alphanumeric and other keys for communicating information and/or command selections to the processor 602 via the I/O port 608.

The environment transducer devices convert one form of energy or signal into another for input into or output from the computing system 600 via the I/O port 608. For example, an electrical signal generated within the computing system 600 may be converted to another type of signal, and/or vice-versa. In one implementation, the environment transducer devices sense characteristics or aspects of an environment local to or remote from the computing device 600, such as battery voltage, open circuit battery voltage, charge current, battery temperature, light, sound, temperature, pressure, magnetic field, electric field, chemical properties, and/or the like.

In one implementation, a communication port 610 may be connected to a network by way of which the computer system 600 may receive network data useful in executing the methods and systems set out herein as well as transmitting information and network configuration changes determined thereby. For example, charging protocols may be updated, battery measurement or calculation data shared with external system, and the like. The communication port 610 connects the computer system 600 to one or more communication interface devices configured to transmit and/or receive information between the computing system 600 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 610 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 600 may include a sub-systems port 612 for communicating with one or more systems related to a device being charged according to the methods and system described herein to control an operation of the same and/or exchange information between the computer system 600 and one or more sub-systems of the device. Examples of such sub-systems of a vehicle, include, without limitation, motor controllers and systems, battery control systems, and others.

The system set forth in FIG. 6 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various operations, which are described in this specification. The operations may be performed by hardware components or may be embodied in machine-executable instructions, which may be used to cause a general-purpose or special-purpose processor programmed with the instructions to perform the operations. Alternatively, the operations may be performed by a combination of hardware, software and/or firmware.

Various modifications and additions can be made to the exemplary embodiments discussed without departing from the scope of the present disclosure. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations, examples and embodiments (terms used synonymously herein) are discussed, it should be understood that this is done for illustration purposes only. A person skilled in the relevant art will recognize that other components and configurations may be used without parting from the spirit and scope of the disclosure. Thus, the description and drawings are illustrative and are not to be construed as limiting. Numerous specific details are described to provide a thorough understanding of the disclosure. However, in certain instances, well-known or conventional details are not described in order to avoid obscuring the description.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance” or similar phrases, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given above. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Various features and advantages of the disclosure are set forth in the description above, and in part will be obvious from the description, or can be learned by practice of the herein disclosed principles. The features and advantages of the disclosure can be realized and obtained by means of the instruments and combinations particularly pointed out in the appended claims.

### Claims

Note: The claims provided herein to preserve intellectual property rights in foreign jurisdictions. As such, the claims provided in this Provisional Application should not be used to implicate any theories of estoppel and/or disclaimer in any non-provisional applications filed in the United States that claim priority hereto (whether directly or indirectly via a continuation, continuation-in-part, divisional, or any other continuing application). Rather, the claims represent just one embodiment of the present invention, as contemplated at the time of filing this Provisional Application. Various other embodiments are contemplated.

What is claimed is:

1. A method of processing a battery comprising:
in a battery comprising an electrode including pores filled with a gas, applying a formation current to the battery, the formation current comprising at least one frequency attribute, the at least one frequency attribute based on an assessed dielectric attribute associated with wetting the pores with electrolyte.

2. The method of claim 1 wherein the assessed dielectric attribute represents a changing dielectric property of the electrode responsive to electrolyte replacing the gas in the pores of the electrode.

3. The method of claim 2 further comprising tuning the at least one frequency attribute based on the changing dielectric property.

4. The method of claim 3 where the at least one frequency attribute targets electrodynamic diffusion processes associated with optimizing wetting of relatively smaller pores with relatively higher surface tension that inhibits electrolyte from entering the pores.

5. The method of claim 1 where the at least one frequency attribute is an alternating current portion of the formation current, with the alternating current applied at a frequency in the range of 1 Ghz to 20 Ghz, or 100 KHz or greater, or 10 MHz or greater.

6. The method of claim 1 further comprising obtaining at least one responsive attribute of a signal applied to the battery where the at least one responsive attribute is indicative of the assessed dielectric attribute.

7. The method of claim 6 wherein the at least one responsive attribute is a peak value at a frequency mapped to the assessed dielectric attribute.

8. The method of claim 1 wherein the assessed dielectric property is obtained from comparing at least one signal peak of a measured signal to a fingerprint that associates the at least one signal peak to a dielectric property.

9. The method of claim 8 wherein the measured signal includes reflected energy, return loss, transmission energy, or transmission loss.

10. A method of processing a battery comprising:
in a battery comprising an electrode, applying a formation current to the battery comprising at least one frequency attribute, the at least one frequency attribute based on an assessed dielectric attribute associated with forming a solid electrolyte interphase (SEI) layer on the electrode.

11. The method of claim 10 further comprising assessing SEI formation progress by comparing a fingerprint including at least one frequency value associated with a dielectric value of a target SEI layer with a signal including at least one frequency value associated with the dielectric value of the target SEI layer.

12. The method of claim 11 wherein the signal includes reflected energy, return loss, transmission energy, or transmission loss.

13. The method of claim 11 further comprising altering the at least one frequency attribute of the formation current based on the comparison.

14. The method of claim 10 wherein the frequency attribute is an alternating current sinusoidal portion of the formation current, the battery is a lithium-ion battery and the electrode is an anode and the SEI layer is on the anode and adjacent an electrolyte.

15. The method of claim 11 wherein the SEI layer is completed without heating the battery.

16. A method of forming a battery comprising:
applying a formation signal to the battery to form a solid electrolyte interphase layer or wetting pores of an electrode with electrolyte, the formation signal comprising a leading edge shaped according to a sinusoid followed by a constant current portion, and an alternating current sinusoidal electrokinetic formation portion.

17. The method of claim 16 wherein the alternating current sinusoidal electrokinetic formation portion is in the range of 1 Ghz to 10 Ghz.

18. The method of claim 17 wherein the alternating current electrokinetic sinusoidal portion is applied during a rest period following the constant current portion.

19. The method of claim 18 wherein the alternating current sinusoidal portion applied during the rest period following the constant current portion is a half wave rectified alternating current or full wave rectified alternating current.

20. The method of claim 16 wherein the alternating current sinusoidal electrokinetic formation portion is applied on the constant current portion.

21. A formation system comprising:
a fixture for holding a battery undergoing formation, the battery comprising at least one electrode and defining a periphery of the at least one electrode;
the fixture defining a conductive chargeable surface adjacent the periphery of the at least one electrode;
the system configured to charge the peripheral conductive surface while the battery is undergoing formation.

22. The formation system of claim 21 wherein the peripheral conductive surface is configured to be positively charged, negatively charged, or to with an alternating charge.
